(19) United States
(12) Patent Application Publication
(10) Pub. No.: US 2026/0342026 A1
(43) Pub. Date: Oct. 29, 2026

(54) CONVERSION CIRCUIT AND CIRCUIT BOARD

(71) Applicant: YOKOWO CO., LTD., Tokyo (JP)

(72) Inventor: Masaki NOGUCHI, Tomioka-shi (JP)

(73) Assignee: YOKOWO CO., LTD., Tokyo (JP)

(21) Appl. No.: 19/408,396

(22) Filed: Dec. 4, 2025

(30) Foreign Application Priority Data
Dec. 20, 2024 (JP) 2024-224679

(51) Int. Cl. H01R 24/44; H01R 24/50; H05K 1/02

(52) U.S. Cl. CPC H01R 24/44; H01R 24/50; H05K 1/0253

(57) ABSTRACT

A conversion circuit includes a coaxial connector and a substrate. The coaxial connector has a core. The substrate includes a first conductor that surrounds the core and is electrically connected to the core, a second conductor that is electrically connected to the first conductor and extends away from the first conductor, and a ground conductor that at least partially overlaps the second conductor. The ground conductor defines an opening that at least partially overlaps the first conductor. The edge of the opening of the ground conductor includes a first portion that surrounds the core except for a side of the core where the second conductor is located, and a second portion that is indented further than the first portion from the side of the core where the second conductor is located toward a side where the core is located.

This application is based on Japanese patent application No. 2024-224679, the content of which is incorporated hereinto by reference.

### BACKGROUND

### Technical Field

The present invention relates to a conversion circuit and a circuit board.

### Related Art

In recent years, various conversion circuits for converting a transmission signal between a coaxial connector and a microstrip line have been developed.

US Patent Application Publication No. 2014/0342581 describes a vertically mounted printed circuit board (PCB) coaxial connector connected to a microstrip line. A printed wiring board (PWB) having a microstrip line has a ground, four plated holes connected to a coaxial connector, and six vias.

### SUMMARY

### Technical Problem

In the conversion circuit, the transmission signal may be converted between the coaxial connector and the microstrip line. However, depending on conditions such as the shape of a ground conductor constituting the microstrip line, it may be difficult to suppress the characteristic impedance mismatch. The difficulty in suppressing the characteristic impedance mismatch can make it challenging to improve the transmission characteristics of the conversion circuit.

An example of the object of the present invention is to improve transmission characteristics of the conversion circuit between the coaxial connector and the microstrip line. Other objects of the present invention will become apparent from the description of the present specification.

An aspect of the present invention is a conversion circuit. The conversion circuit includes a coaxial connector and a substrate. The coaxial connector has a core. The substrate including a first conductor that surrounds the core and is electrically connected to the core, a second conductor that is electrically connected to the first conductor and extends away from the first conductor, and a ground conductor that at least partially overlaps the second conductor. The ground conductor defines an opening that at least partially overlaps the first conductor. The edge of the opening of the ground conductor includes a first portion that surrounds the core except for a side of the core where the second conductor is located, and a second portion that is indented further than the first portion from the side of the core where the second conductor is located toward a side where the core is located.

An aspect of the present invention is a circuit board. The circuit board includes a first conductor that surrounds a core of a coaxial connector and is electrically connected to the core, a second conductor that is electrically connected to the first conductor and extends away from the first conductor, and a ground conductor that at least partially overlaps the second conductor. The ground conductor defines an opening that at least partially overlaps the first conductor. The edge of the opening of the ground conductor includes a first portion that surrounds the core except for a side of the core where the second conductor is located, and a second portion that is indented further than the first portion from the side of the core where the second conductor is located toward a side where the core is located.

According to the above-described aspect of the present invention, the transmission characteristics of the conversion circuit between the coaxial connector and the microstrip line can be improved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is an exploded perspective view of a conversion circuit according to an embodiment;

FIG. 2 is a plan view of a core, a center land, a tapered conductor, a line conductor, four peripheral lands, and a ground conductor according to the embodiment;

FIG. 3 is a plan view of the core and the ground conductor according to the embodiment;

FIG. 4 is a plan view of a core, a center land, a tapered conductor, a line conductor, a peripheral conductor, and a ground conductor according to a comparative example;

FIG. 5 is a plan view of the core and the ground conductor according to the comparative example;

FIG. 6 is a graph showing time domain reflectometry (TDR) characteristics of the conversion circuit according to the embodiment and the conversion circuit according to the comparative example;

FIG. 7 is a graph showing frequency characteristics of the insertion loss of the conversion circuit according to the embodiment and the conversion circuit according to the comparative example; and

FIG. 8 is a graph showing frequency characteristics of the return loss of the conversion circuit according to the embodiment and the conversion circuit according to the comparative example.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, an embodiment of the present invention will be described with reference to the drawings. In all drawings, the same constituent elements are denoted by the same reference signs, and detailed description thereof will not be repeated.

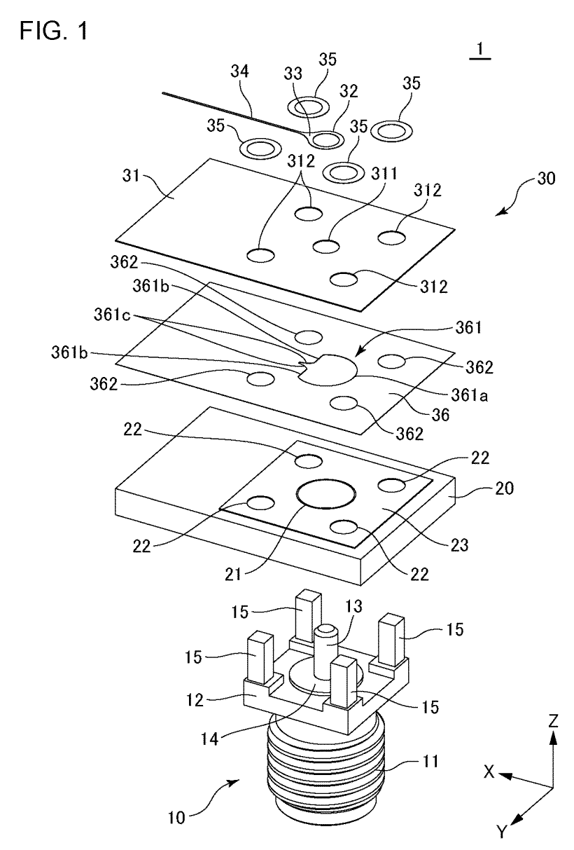

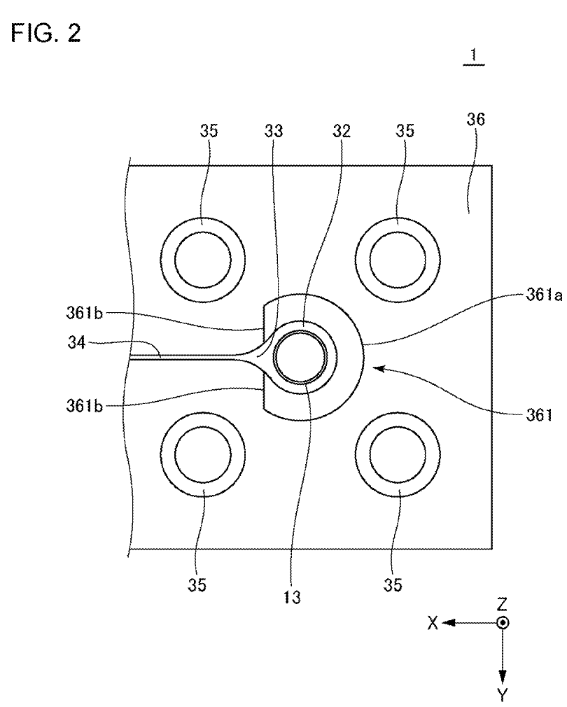

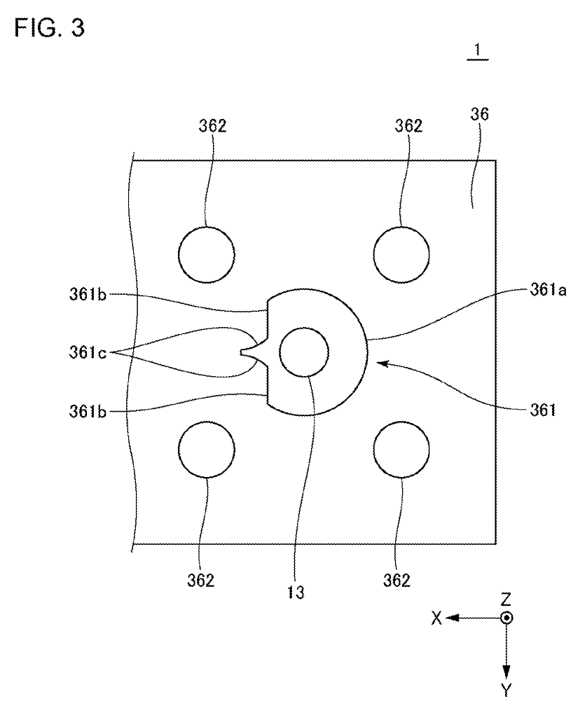

FIG. 1 is an exploded perspective view of a conversion circuit 1 according to an embodiment. FIG. 2 is a plan view of a core 13, a center land 32, a tapered conductor 33, a line conductor 34, four peripheral lands 35, and a ground conductor 36 according to the embodiment. FIG. 3 is a plan view of the core 13 and the ground conductor 36 according to the embodiment.

In FIGS. 1 to 3, the X-axis, the Y-axis, and the Z-axis indicating the X direction, the Y direction, and the Z direction, respectively, are shown for description. In FIGS. 2 and 3, the white circle with a black dot indicating the Z-axis indicates that the arrow of the Z-axis points to the front of the paper surface. The Z direction is a direction parallel to an arrangement direction of the coaxial connector 10, the holding body 20, and the substrate 30, which will be described later. The X direction is one of directions perpendicular to the Z

direction. The Y direction is one of a direction perpendicular to the Z direction and the X direction. Hereinafter, unless otherwise specified, the +X side refers to a side indicated by the arrow of the X-axis, and the -X side refers to a side opposite to the side indicated by the arrow of the X-axis. Hereinafter, unless otherwise specified, the +Y side refers to a side indicated by the arrow of the Y-axis, and the -Y side refers to a side opposite to the side indicated by the arrow of the Y-axis. Hereinafter, unless otherwise specified, the +Z side refers to a side indicated by the arrow of the Z-axis, and the -Z side refers to a side opposite to the side indicated by the arrow of the Z-axis. Hereinafter, a surface of an element positioned on the +Z side may be referred to as a +Z surface of the element, and a surface of the element positioned on the -Z side may be referred to as a -Z surface of the element.

The conversion circuit 1 according to the embodiment will be mainly described with reference to FIG. 1. FIGS. 2 and 3 will be referred to as necessary.

As shown in FIG. 1, the conversion circuit 1 according to the embodiment includes the coaxial connector 10, the holding body 20, and the substrate 30.

The coaxial connector 10 is a Sub Miniature type A (SMA) connector. The coaxial connector 10 may be a connector of a type different from the SMA connector. As shown in FIG. 1, the coaxial connector 10 includes a housing 11, a flange 12, a core 13, an insulator 14, and four posts 15.

The housing 11 is made of a conductor such as metal. The housing 11 has a substantially cylindrical shape. A screw thread for joining with a coaxial cable (not shown) is defined on an outer peripheral surface of the housing 11 around the Z direction. The housing 11 may not define the screw thread.

The flange 12 is made of a conductor such as metal. The +Z side end portion of the housing 11 and the -Z surface of the flange 12 are electrically connected to each other. In the embodiment, the housing 11 and the flange 12 are integrally formed. As shown in FIG. 1, the flange 12 has a substantially square shape having a pair of sides generally parallel to the X direction and a pair of sides generally parallel to the Y direction as viewed from the +Z side. The lengths of the flange 12 in the X direction and the Y direction are longer than the diameter in the direction perpendicular to the Z direction of the housing 11 as viewed from the +Z side. The shape of the flange 12 is not limited to the example shown in FIG. 1. For example, the flange 12 may have a substantially rectangular shape or a substantially circular shape as viewed from the +Z side.

The core 13 is made of a conductor such as metal. As shown in FIG. 1, the core 13 extends in the Z direction. The core 13 is positioned substantially at the center of the housing 11 and the flange 12 as viewed from the +Z side. The +Z side end portion of the core 13 protrudes from the +Z surface of the flange 12 to the +Z side. A portion of the core 13 that is located inside the housing 11 and the flange 12 is covered with the insulator 14 embedded in the housing 11 and the flange 12. Therefore, the conductor constituting the core 13 and the conductor constituting the housing 11 and the flange 12 are electrically insulated from each other by the insulator 14.

Each post 15 is made of a conductor such as metal. As shown in FIG. 1, the four posts 15 protrude toward the +Z side from the four corners of the +Z surface of the flange 12 as viewed from the +Z side. The +Z surface of the flange 12 and the -Z side end portions of the four posts 15 are electrically connected to each other. In the embodiment, the flange 12 and the four posts 15 are integrally formed.

The holding body 20 is made of an insulator such as glass epoxy. The holding body 20 may be made of a metal. As shown in FIG. 1, the holding body 20 has a substantially plate shape generally perpendicular to the Z direction.

As shown in FIG. 1, the holding body 20 defines a central insertion hole 21 and four peripheral insertion holes 22 positioned around the central insertion hole 21 in the Z direction. The central insertion hole 21 and the four peripheral insertion holes 22 penetrate the holding body 20 in the Z direction. As can be seen from FIG. 1, when the coaxial connector 10 and the holding body 20 are assembled with each other, the core 13 is inserted into the central insertion hole 21, and the four posts 15 are inserted into the four peripheral insertion holes 22. The four posts 15 are inserted into the four peripheral insertion holes 22, so that the coaxial connector 10 is held by the holding body 20.

As shown in FIG. 1, a conductor layer 23 is formed on a +Z surface of the holding body 20, an inner surface of the central insertion hole 21 in the Z direction, and inner surfaces of the four peripheral insertion holes 22 in the Z direction. The conductor layer 23 is also formed on the -Z surface side of the holding body 20. The conductor layer 23 is, for example, a metal layer. In the example shown in FIG. 1, the conductor layer 23 formed on the +Z surface side of the holding body 20 has a substantially quadrangular shape centered on the central insertion hole 21, the conductor layer 23 having a pair of sides generally parallel to the X direction and a pair of sides generally parallel to the Y direction. The four peripheral insertion holes 22 are positioned at four corners of the conductor layer 23 as viewed from the +Z side.

The substrate 30 is a circuit board. In the embodiment, the substrate 30 is a flexible substrate such as a flexible printed circuit (FPC). The substrate 30 may be a rigid substrate such as a printed circuit board (PCB). As shown in FIG. 1, the substrate 30 has a film 31, a center land 32, a tapered conductor 33, a line conductor 34, four peripheral lands 35, and a ground conductor 36.

The film 31 is made of, for example, a resin such as polyimide. As shown in FIG. 1, the film 31 has a substantially sheet shape extending in a direction generally perpendicular to the Z direction. The film 31 has flexibility. Therefore, the film 31 can be deformed with a relatively high degree of freedom. The film 31 defines a central through-hole 311 and four peripheral through-holes 312 positioned around the central through-hole 311 in the Z direction. The central through-hole 311 and the four peripheral through-holes 312 penetrate the film 31 in the Z direction. The central insertion hole 21 and the central through-hole 311 at least partially overlap each other in the Z direction. The four peripheral insertion holes 22 and the four peripheral through-holes 312 at least partially overlap each other in the Z direction.

As shown in FIG. 1, the center land 32, the tapered conductor 33, and the line conductor 34 are conductors provided on the +Z surface side of the film 31. The center land 32, the tapered conductor 33, and the line conductor 34 are, for example, metal layers formed on the +Z surface side of the film 31. In the embodiment, the center land 32, the tapered conductor 33, and the line conductor 34 are integrally formed.

As shown in FIG. 1, the central through-hole 311 and the center land 32 partially overlap each other in the Z direction. As can be seen from FIG. 1, when the coaxial connector 10, the holding body 20, and the substrate 30 are assembled with each other, the center land 32 has a surrounding shape that surrounds the +Z side end portion of the core 13 about the Z direction as viewed from the +Z side. In the example shown in FIG. 1, the center land 32 has a substantially annular shape that surrounds the +Z side end portion of the core 13 about the Z direction as viewed from the +Z side. Hereinafter, unless otherwise specified, the hole of the center land 32 refers to a hole surrounded by the inner periphery of the center land 32 in the Z direction.

As shown in FIGS. 1 and 2, the line conductor 34 extends in the X direction to the +X side away from the center land 32 with the tapered conductor 33 positioned at the +X side end portion of the center land 32 and the -X side end portion of the line conductor 34. The +X side end portion of the center land 32 and the -X side end portion of the tapered conductor 33 are electrically connected to each other. The +X side end portion of the tapered conductor 33 and the -X side end portion of the line conductor 34 are electrically connected to each other. Accordingly, the center land 32 and the line conductor 34 are electrically connected to each other through the tapered conductor 33. The width of the tapered conductor 33 in the Y direction continuously decreases from the center land 32 toward the line conductor 34. The width of the line conductor 34 in the Y direction is substantially constant regardless of the position of the line conductor 34 in the X direction.

In the embodiment, as shown in FIG. 2, the +X side end portion of the center land 32 and the -X side end portion of the line conductor 34 are connected to each other via the tapered conductor 33. Therefore, the change in the Y directional width of the conductors forming the center land 32 and the line conductor 34 between the +X side end portion of the center land 32 and the -X side end portion of the line conductor 34 can be more gradual than when the +X side end portion of the center land 32 and the -X side end portion of the line conductor 34 are directly connected to each other without the tapered conductor 33. Accordingly, the conductors constituting the center land 32 and the line conductor 34 between the +X side end portion of the center land 32 and the -X side end portion of the line conductor 34 can be prevented from being disconnected as compared with a case where the change in the Y directional width of the conductors constituting the center land 32 and the line conductor 34 between the +X side end portion of the center land 32 and the -X side end portion of the line conductor 34 is steep. The +X side end portion of the center land 32 and the -X side end portion of the line conductor 34 may be directly connected to each other without via the tapered conductor 33.

As shown in FIG. 1, the four peripheral lands 35 are conductors provided on the +Z surface side of the film 31. The four peripheral lands 35 are, for example, metal layers formed on the +Z surface side of the film 31. The four peripheral through-holes 312 and the four peripheral lands 35 partially overlap each other in the Z direction. As can be seen from FIG. 1, when the coaxial connector 10, the holding body 20, and the substrate 30 are assembled with each other, the four peripheral lands 35 have a surrounding shape that surrounds the +Z side end portions of the four posts 15 about the Z direction as viewed from the +Z side. In the example shown in FIG. 1, the four peripheral lands 35 have a substantially annular shape that surrounds the +Z side end portions of the four posts 15 about the Z direction as viewed from the +Z side. Hereinafter, unless otherwise specified, the hole of the peripheral land 35 refers to a hole surrounded by the inner periphery of the peripheral land 35 in the Z direction.

As shown in FIG. 1, the ground conductor 36 is a conductor provided on the -Z surface side of the film 31. The ground conductor 36 is, for example, a metal layer formed on the -Z surface side of the film 31. The ground conductor 36 defines a central opening 361 and four peripheral openings 362 positioned around the central opening 361 in the Z direction. The central insertion hole 21, the central through-hole 311, and the central opening 361 at least partially overlap each other in the Z direction. The four peripheral insertion holes 22, the four peripheral through-holes 312, and the four peripheral openings 362 at least partially overlap each other in the Z direction.

The line conductor 34 and the ground conductor 36 constitute a microstrip line. Specifically, in the example shown in FIG. 1, the ground conductor 36 is located substantially on the -Z surface of the film 31 except for the central opening 361 and the four peripheral openings 362. Therefore, the line conductor 34 and the ground conductor 36 at least partially overlap each other in the Z direction. By adjusting conditions such as the width of the line conductor 34 in the Y direction, the thickness of the line conductor 34 in the Z direction, and the distance in the Z direction between the -Z surface of the line conductor 34 and the +Z surface of the ground conductor 36, the line conductor 34 and the ground conductor 36 can configure a microstrip line having a predetermined characteristic impedance. The conversion circuit 1 is configured to convert a transmission signal between the coaxial connector 10 and a microstrip line composed of the line conductor 34 and the ground conductor 36.

As can be seen from FIG. 1, when the coaxial connector 10, the holding body 20, and the substrate 30 are assembled with each other, the four posts 15 penetrate the holes of the four peripheral insertion holes 22, the four peripheral openings 362, the four peripheral through-holes 312, and the four peripheral lands 35 in the Z direction. The +Z side end portion of each post 15 and each peripheral land 35 are joined to each other by, for example, soldering. The solder joining the +Z side end portion of each post 15 and each peripheral land 35 to each other also enters a gap between the outer surface of each post 15 around the Z direction and the inner surface of each peripheral opening 362 around the Z direction. In addition, when the holding body 20 and the substrate 30 are stacked on each other in the Z direction, the +Z surface of the conductor layer 23 and the -Z surface of the ground conductor 36, which are located on the +Z surface side of the holding body 20, are in contact with each other. Therefore, when the +Z side end portion of each post 15 and each peripheral land 35 are joined to each other by soldering, each post 15, the conductor layer 23, each peripheral land 35, and the ground conductor 36 are electrically connected to each other.

As can be seen from FIG. 1, when the coaxial connector 10, the holding body 20, and the substrate 30 are assembled with each other, the core 13 penetrates the holes of the central insertion hole 21, the central opening 361, the central through-hole 311, and the center lands 32 in the Z direction. The core 13 is inserted into the central insertion hole 21 with the outer surface of the core 13 around the Z direction and the conductor layer 23 formed on the inner surface of the central insertion hole 21 around the Z direction spaced apart from each other. Therefore, the core 13 and the conductor layer 23 are not conductive. The core 13 is inserted into the central opening 361 in a with the outer surface of the core 13 around the Z direction and the curved edge 361a, the pair of straight edges 361b, and the pair of tapered edges 361c of the central opening 361 around the Z direction spaced apart from each other. Therefore, the core 13 and the ground conductor 36 are not conductive. Details of the curved edge 361a, the pair of straight edges 361b, and the pair of tapered edges 361c will be described later with reference to FIGS. 2 and 3. The +Z side end portion of the core 13 and the center land 32 are joined to each other by, for example, soldering. The +Z side end portion of the core 13 and the center land 32 are joined to each other by soldering, so that the core 13 and the center land 32 are electrically connected to each other. Therefore, the coaxial connector 10 and the microstrip line composed of the line conductor 34 and the ground conductor 36 can be electrically connected to each other.

In the embodiment, a coaxial structure is formed by the core 13 and the conductor layer 23 formed on the inner surface of the central insertion hole 21 in the Z direction. The coaxial structure can be configured to match the characteristic impedance of the coaxial connector 10 and the characteristic impedance of the microstrip line composed of the line conductor 34 and the ground conductor 36 by adjusting dimensions such as the diameter of the core 13 in a direction perpendicular to the Z direction, the diameter of the central insertion hole 21 in a direction perpendicular to the Z direction, and the distance between the outer surface of the core 13 around the Z direction and the inner surface of the central insertion hole 21 around the Z direction.

Next, the central opening 361 of the ground conductor 36 according to the embodiment will be further described with reference to FIGS. 2 and 3.

As shown in FIGS. 2 and 3, the edge of the central opening 361 around the Z direction includes a curved edge 361a, a pair of straight edges 361b, and a pair of tapered edges 361c. As shown in FIG. 3, the central opening 361 has a substantially circular shape that partially has a curved edge 361a as a part of a circumference and is partially missing by a pair of straight edges 361b and a pair of tapered edges 361c as viewed from the +Z side. In the examples shown in FIGS. 2 and 3, in the projection of the center land 32 and the ground conductor 36 on the plane perpendicular to the Z direction as viewed from the +Z side, the center land 32 and the circular shape are substantially concentric. As can be seen from FIGS. 2 and 3, when viewed from the +Z side, the curved edge 361a surrounds the core 13 around the Z direction except for the +X side of the core 13 where the line conductor 34 is located. As can be seen from FIGS. 2 and 3, when viewed from the +Z side, the pair of straight edges 361b and the pair of tapered edges 361c are indented further than the curved edge 361a from the +X side of the core 13 where the line conductor 34 is positioned toward the -X side where the core 13 is positioned. In the example shown in FIG. 3, the pair of straight edges 361b extends in the Y direction from both ends of the curved edge 361a on both sides of the tapered conductor 33 in the Y direction toward each other. The pair of tapered edges 361c extend from the ends of the pair of straight edges 361b facing each other in the Y direction to the +X side. A distance in the Y direction between the pair of tapered edges 361c decreases toward the +X side.

As can be seen from FIGS. 2 and 3, both edges of the tapered conductor 33 in the Y direction and the pair of tapered edges 361c are arranged generally parallel to each other at least partially. The both edges of the tapered conductor 33 in the Y direction and the pair of tapered edges 361c may at least partially overlap each other in the Z direction as viewed from the +Z side. Alternatively, in the projection of the tapered conductor 33 and the pair of tapered edges 361c on the plane perpendicular to the Z direction as viewed from the +Z side, both edges of the tapered conductor 33 in the Y direction and the pair of tapered edges 361c may be positioned to be shifted from each other.

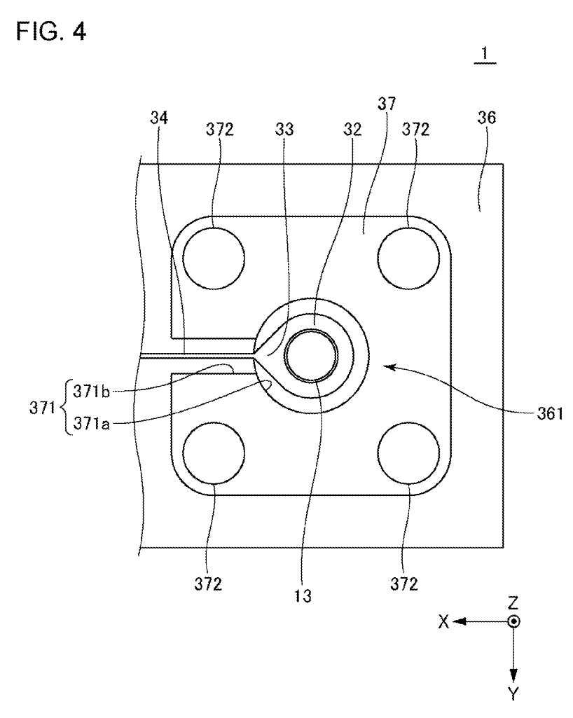

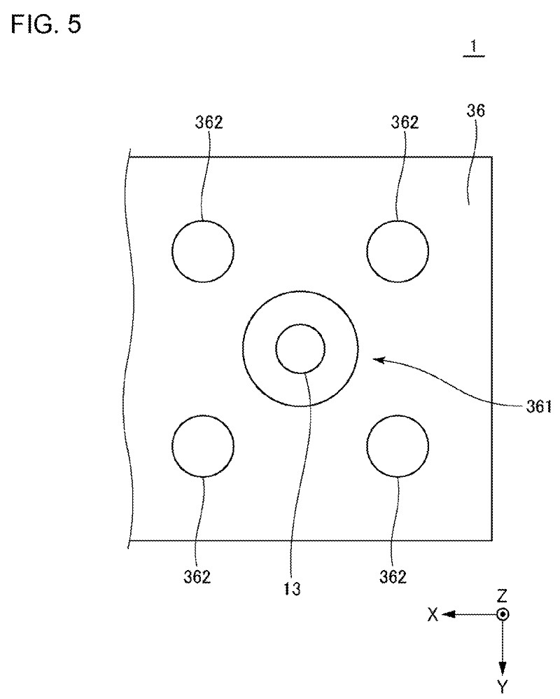

FIG. 4 is a plan view of a core 13, a center land 32, a tapered conductor 33, a line conductor 34, a peripheral conductor 37, and a ground conductor 36 according to a comparative example. FIG. 5 is a plan view of the core 13 and the ground conductor 36 according to the comparative example. The conversion circuit 1 according to the comparative example is the same as the conversion circuit 1 according to the embodiment except for the following points.

As shown in FIG. 4, the peripheral conductor 37 according to the comparative example has a substantially square shape having a pair of sides generally parallel to the X direction and a pair of sides generally parallel to the Y direction, and having rounded four corners, as viewed from the +Z side. As shown in FIG. 4, the peripheral conductor 37 defines a notch pattern 371 and four opening patterns 372 positioned around the notch pattern 371 in the Z direction. As can be seen from FIGS. 4 and 5, the notch pattern 371 includes a circular pattern 371a that overlaps the central opening 361 in the Z direction, and a straight line pattern 371b that extends in the X direction between the +X side end portion of the circular pattern 371a and the Y directional substantially center of the +X side of the peripheral conductor 37. The center land 32 and the tapered conductor 33 are positioned in the circular pattern 371a. The line conductor 34 passes through the straight line pattern 371b on the +X side of the center land 32 and the tapered conductor 33. As can be seen from FIGS. 4 and 5, the four opening patterns 372 are positioned at four corners of the peripheral conductor 37 and overlap the four peripheral openings 362 in the Z direction as viewed from the +Z side.

As shown in FIG. 5, the central opening 361 according to the comparative example has a simple circular shape as viewed from the +Z side. In other words, the central opening 361 according to the comparative example does not include the edge corresponding to the pair of straight edges 361b and the pair of tapered edges 361c according to the embodiment.

The conversion circuit 1 according to the embodiment and the conversion circuit 1 according to the comparative example are compared with each other.

In the conversion circuit 1 according to the comparative example, the characteristic impedance of the tapered conductor 33 located at a connection point between the +X side end portion of the center land 32 and the -X side end portion of the line conductor 34 is likely to be larger than the characteristic impedance of the coaxial connector 10 or the characteristic impedance of the microstrip line composed of the line conductor 34 and the ground conductor 36. Therefore, in the conversion circuit 1 according to the comparative example, it may be difficult to suppress the characteristic impedance mismatch of the tapered conductor 33. In the embodiment, the +X side edge of the central opening 361 is indented toward the -X side where the core 13 is located by the pair of straight edges 361b and the pair of tapered edges 361c, as compared with the comparative example. Therefore, in the embodiment, the tapered conductor 33 and the ground conductor 36 can be brought close to each other as compared with the comparative example. Therefore, in the embodiment, the characteristic impedance of the tapered conductor 33 can be reduced as compared with the comparative example, and the characteristic impedance mismatch of the tapered conductor 33 can be suppressed. Accordingly, in the embodiment, the transmission characteristics of the conversion circuit 1 between the coaxial connector 10 and the microstrip line composed of the line conductor 34 and the ground conductor 36 can be improved as compared with the comparative example.

As described above, the +X side edge of the central opening 361 is indented toward the -X side where the core 13 is located, so that the characteristic impedance of the tapered conductor 33 can be reduced. However, when the +X side edge of the central opening 361 is simply indented toward the -X side, the characteristic impedance of the tapered conductor 33 may be excessively low. In the conversion circuit 1 according to the embodiment, both edges of the tapered conductor 33 in the Y direction and the pair of tapered edges 361c are arranged generally parallel to each other. Therefore, by adjusting the distance between both edges of the tapered conductor 33 in the Y direction and the pair of tapered edges 361c to an appropriate distance, the characteristic impedance of the tapered conductor 33 can be adjusted to an appropriate value for matching the characteristic impedance of the coaxial connector 10 and the characteristic impedance of the microstrip line composed of the line conductor 34 and the ground conductor 36. Depending on the characteristic impedance of the tapered conductor 33, the +X side edge of the central opening 361 may be simply indented toward the -X side.

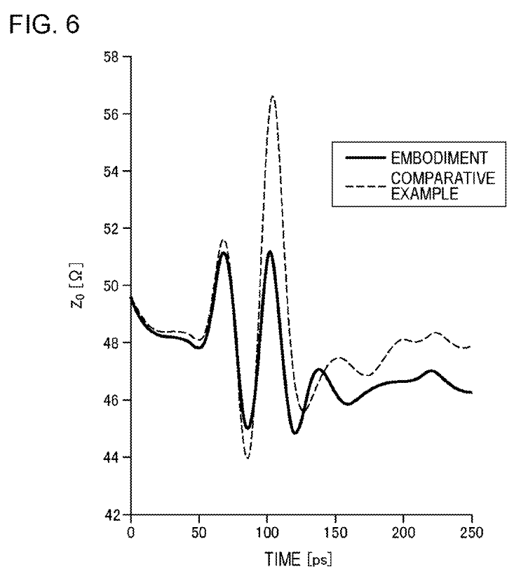

FIG. 6 is a graph showing time domain reflectometry (TDR) characteristics of the conversion circuit 1 according to the embodiment and the conversion circuit 1 according to the comparative example. A horizontal axis of the graph shown in FIG. 6 indicates time (unit: ps). A vertical axis of the graph shown in FIG. 6 indicates the characteristic impedance Z₀ (unit: Ω). In the graph shown in FIG. 6, the impedance of the coaxial cable electrically connected to the coaxial connector 10 is 50 Ω.

A time region of 0 ps to 250 ps in the graph shown in FIG. 6 is divided into the following time regions. That is, 0 ps to about 50 ps is a time region corresponding to the housing 11 according to the embodiment and the comparative example. About 50 ps to about 85 ps is a time region corresponding to the holding body 20 according to the embodiment and the comparative example. About 85 ps to about 130 ps is a time region corresponding to the tapered conductor 33 according to the embodiment and the comparative example. About 130 ps to about 250 ps is a time region corresponding to the line conductor 34 according to the embodiment and the comparative example.

As shown in FIG. 6, the maximal value of the characteristic impedance Z₀(unit: Ω) at about 100 ps is a value closer to the impedance of 50 Ω of the coaxial cable in the embodiment than in the comparative example. From the results shown in FIG. 6, the characteristic impedance Z₀ of the tapered conductor 33 can be reduced by allowing the +X side edge of the central opening 361 to be indented further than the curved edge 361a toward the -X side where the core 13 is located.

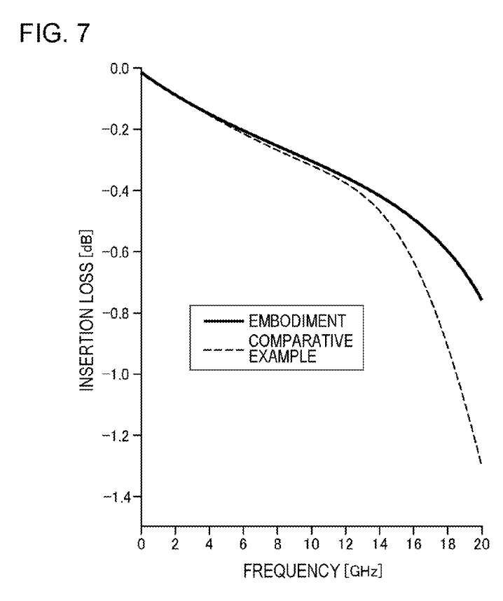

FIG. 7 is a graph showing frequency characteristics of the insertion loss of the conversion circuit 1 according to the embodiment and the conversion circuit 1 according to the comparative example. The horizontal axis of the graph shown in FIG. 7 indicates the frequency (unit: GHz). The vertical axis of the graph shown in FIG. 7 indicates the insertion loss (unit: dB). In the graph shown in FIG. 7, as the absolute value of the negative value of the vertical axis increases, the insertion loss of the conversion circuit 1 increases.

As shown in FIG. 7, at about 6 GHz to about 20 GHz, the insertion loss is smaller in the embodiment than in the comparative example. From the results shown in FIG. 7, the passing characteristics of the transmission signal of the conversion circuit 1 can be improved in a wide band by allowing the +X side edge of the central opening 361 to be indented further than the curved edge 361a toward the -X side where the core 13 is located.

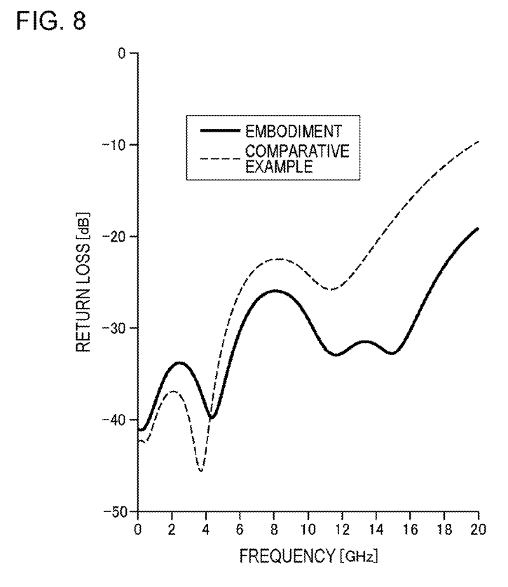

FIG. 8 is a graph showing frequency characteristics of the return loss of the conversion circuit 1 according to the embodiment and the conversion circuit 1 according to the comparative example. The horizontal axis of the graph shown in FIG. 8 indicates the frequency (unit: GHz). The vertical axis of the graph shown in FIG. 8 indicates the return loss (unit: dB). In the graph shown in FIG. 8, as the absolute value of the negative value of the vertical axis increases, the return loss of the conversion circuit 1 decreases.

As shown in FIG. 8, at about 6 GHz to about 20 GHz, the return loss is smaller in the embodiment than in the comparative example. From the results shown in FIG. 8, the reflection characteristics of the transmission signal of the conversion circuit 1 can be improved in a wide band by allowing the +X side edge of the central opening 361 to be indented further than the curved edge 361a toward the -X side where the core 13 is located.

Hereinabove, the embodiments of the present invention have been described with reference to the drawings. However, the embodiment is merely an example of the present invention, and various configurations other than the above-described configurations can also be adopted.

According to the present specification, a conversion circuit and a circuit board of the following aspects are provided.

### Aspect 1

In the aspect 1, the conversion circuit includes a coaxial connector and a substrate. The coaxial connector has a core. The substrate includes a first conductor that surrounds the core and is electrically connected to the core, a second conductor that is electrically connected to the first conductor and extends away from the first conductor, and a ground conductor that at least partially overlaps the second conductor. The ground conductor defines an opening that at least partially overlaps the first conductor. The edge of the opening of the ground conductor includes a first portion that surrounds the core except for a side of the core where the second conductor is located, and a second portion that is indented further than the first portion from the side of the core where the second conductor is located toward a side where the core is located.

The "first conductor" corresponds to the "center land" of the above-described embodiment. The "second conductor" corresponds to the "line conductor" of the above-described embodiment. The "opening" corresponds to the "central opening" of the above-described embodiment. The "first portion" corresponds to the "curved edge" of the above-described embodiment. The "second portion" corresponds to the "straight edge" and the "tapered edge" of the above-described embodiment.

According to the above-described aspect, the connecting portion between the first conductor and the second conductor and the ground conductor can be brought close to each other as compared with a case where the second portion is not indented toward the side where the core is located. Therefore, the characteristic impedance at the connecting portion between the first conductor and the second conductor can be reduced as compared with the case where the second portion is not indented toward the side where the core is located, and the characteristic impedance mismatch at the connecting portion between the first conductor and the second conductor can be suppressed. Therefore, the transmission characteristics of the conversion circuit between the coaxial connector and the microstrip line composed of the second conductor and the ground conductor can be improved as compared with the case where the second portion is not indented toward the side where the core is located.

### Aspect 2

In the aspect 2, the substrate further includes a third conductor that electrically connects the first conductor and the second conductor and has a width that decreases from the first conductor toward the second conductor. The edge of the third conductor and the second portion of the edge of the opening are arranged at least partially generally parallel to each other.

The "third conductor" corresponds to the "tapered conductor" of the above-described embodiment. The "second portion" corresponds to the "tapered edge" of the above-described embodiment.

According to the above-described aspect, by adjusting the distance between the edge of the third conductor and the second portion of the edge of the opening to an appropriate distance, the characteristic impedance of the connection point between the first conductor and the second conductor can be adjusted to an appropriate value for matching the characteristic impedance of the coaxial connector and the characteristic impedance of the microstrip line composed of the second conductor and the ground conductor.

### Aspect 3

In the aspect 3, the circuit board includes a first conductor that surrounds a core of a coaxial connector and is electrically connected to the core, a second conductor that is electrically connected to the first conductor and extends away from the first conductor, and a ground conductor that at least partially overlaps the second conductor. The ground conductor defines an opening that at least partially overlaps the first conductor. The edge of the opening of the ground conductor includes a first portion that surrounds the core except for a side of the core where the second conductor is located, and a second portion that is indented further than the first portion from the side of the core where the second conductor is located toward a side where the core is located.

The "circuit board" corresponds to the "substrate" of the above-described embodiment. The "first conductor" corresponds to the "center land" of the above-described embodiment. The "second conductor" corresponds to the "line conductor" of the above-described embodiment. The "opening" corresponds to the "central opening" of the above-described embodiment. The "first portion" corresponds to the "curved edge" of the above-described embodiment. The "second portion" corresponds to the "straight edge" and the "tapered edge" of the above-described embodiment.

According to the above-described aspect, the transmission characteristics of the conversion circuit between the coaxial connector and the microstrip line composed of the second conductor and the ground conductor can be improved as compared with the case where the second portion is not indented toward the side where the core is located.

It is apparent that the present invention is not limited to the above embodiment and may be modified and changed without departing from the scope and spirit of the invention.

### REFERENCE NUMERALS

1 conversion circuit,
10 coaxial connector,
11 housing,
12 flange,
13 core,
14 insulator,
15 post,
20 holding body,
21 central insertion hole,
22 peripheral insertion hole,
23 conductor layer,
30 substrate,
31 film,
311 central through-hole,
312 peripheral through-hole,
32 center land,
33 tapered conductor,
34 line conductor,
35 peripheral land,
36 ground conductor,
361 central opening,
361a curved edge,
361b straight edge,
361c tapered edge,
362 peripheral opening,
37 peripheral conductor,
371 notch pattern,
371a circular pattern,
371b straight line pattern,
372 opening pattern

What is claimed is:

1. A conversion circuit comprising:
a coaxial connector having a core; and
a substrate including a first conductor that surrounds the core and is electrically connected to the core, a second conductor that is electrically connected to the first conductor and extends away from the first conductor, and a ground conductor that at least partially overlaps the second conductor, wherein
the ground conductor defines an opening that at least partially overlaps the first conductor, and
an edge of the opening of the ground conductor includes a first portion that surrounds the core except for a side of the core where the second conductor is located, and a second portion that is indented further than the first portion from the side of the core where the second conductor is located toward a side where the core is located.

2. The conversion circuit according to claim 1, wherein
the substrate further includes a third conductor that electrically connects the first conductor and the second conductor and has a width that decreases from the first conductor toward the second conductor, and
an edge of the third conductor and the second portion of the edge of the opening are arranged at least partially generally parallel to each other.

3. A circuit board comprising:
a first conductor that surrounds a core of a coaxial connector and is electrically connected to the core,
a second conductor that is electrically connected to the first conductor and extends away from the first conductor, and
a ground conductor that at least partially overlaps the second conductor, wherein
the ground conductor defines an opening that at least partially overlaps the first conductor, and
an edge of the opening of the ground conductor includes a first portion that surrounds the core except for a side of the core where the second conductor is located, and a second portion that is indented further than the first portion from the side of the core where the second conductor is located toward a side where the core is located.
